(19) United States
(12) Patent Application Publication
(10) Pub. No.: US 2008/0197856 A1
(43) Pub. Date: Aug. 21, 2008

(54) Circuit Arrangement to Diagnose a Heating Resistor

(75) Inventors: Eberhard Schnaibel, Hemmingen (DE); Rolf Reischl, Stuttgart (DE); Andreas Koring, Reutlingen (DE); Ronaldi Rusli, Stuttgart (DE)

Correspondence Address: MERCHANT & GOULD PC, P.O. BOX 2903, MINNEAPOLIS, MN, 55402-0903, US

(73) Assignee: Robert Bosch GmbH, Stuttgart (DE)

(21) Appl. No.: 11/630,533

(22) PCT Filed: May 12, 2005
(86) PCT No.: PCT/EP2005/052170

§ 371 Date: Dec. 21, 2006

(30) Foreign Application Priority Data
Jun. 30, 2004 (DE) 10 2004 031 625.2

(51) Int. Cl. G01R 31/302

(52) U.S. Cl. 324/549

(57) ABSTRACT

A circuit arrangement is proposed to diagnose a heating resistor, which is connected in series with a first switch, which connects the heating resistor to a power source for operation of the heating resistor with a heating current. Provision is made for means to operate the heating resistor with a diagnostic current during a cut-out time of the heating current and for means to acquire a diagnostic voltage as a measurement for the voltages occurring at the heating resistor as well as means to calculate the resistance of the heating resistor, which is taken as a basis for the diagnosis.

### STATE OF THE ART

The invention proceeds from a circuit arrangement to diagnose a heating resistor according to the class of the independent claim.

A circuit arrangement to heat a component with a heating resistor was made known from the patent EP 979 441 B1, whereby the achievement of an operating temperature of the component to be heated is derived exclusively from the electrical behavior of the heating resistor. Provision is made to ascertain the median energy delivered to the heating resistor within an observable time interval. A shortfall to a specified threshold of the median energy is considered to be at least approximate achievement of a specified operating temperature of the component to be heated. Provision is made in a configuration that the electrical resistance of the heating resistor is assessed as a measurement for its temperature.

From the German patent DE 195 31 786 A1 a circuit arrangement to activate a heating resistor was made known, whereby the temperature of the heating resistor is adjusted to a specified value. The heating resistor is activated by a two-position temperature controller. If set point temperature and actual temperature deviate from each other, the heating resistor is fed with current. The actual temperature of the heating resistor is ascertained indirectly by acquisition of its electrical resistance. The heating resistor is a component part of a voltage divider, through which a small diagnostic current flows during the cut-out phase of a heating current. This current allows for an inference to be drawn about the resistance of the heating resistor by way of the voltage drops at the voltage divider.

The task underlying the invention is to specify a circuit arrangement to diagnose a heating resistor, which delivers exact results using simple means.

The task is solved by the characteristics stated in the independent claim.

### ADVANTAGES OF THE INVENTION

The circuit arrangement according to the invention to diagnose a heating resistor, which is connected in series with a switch, which connects the heating resistor to a power source for the operation of the heating resistor with a heating current, provides for means to operate the heating resistor with a diagnostic current during a cut-out phase of the heating current. Furthermore, provision is made for means to acquire a diagnostic voltage as a measurement for a voltage occurring at the heating resistor, and for means to calculate the resistance of the heating resistor, which is being taken as the basis for the diagnosis.

The diagnosis can be directly based on the resistance, which was ascertained. This resistance is compared to an upper and/or lower threshold value. The diagnosis can furthermore be applied to the heating output, which can be ascertained from the previously ascertained resistance of the heating resistor and the voltage drop occurring at the heating resistor. Taking the operating time into consideration, the heating energy converted into heating resistance can be taken as a basis for the diagnosis. A controller-actuating variable appearing within the circuit arrangement according to the invention, which determines a control pulse of the switch, constitutes an additional diagnostic possibility.

The circuit arrangement according to the invention can be implemented with comparatively low costs and allows for a diagnosis with a comparatively high degree of accuracy. A considerable advantage can be seen therein, that amplifier stages are not required. An additional advantage is it's toughness in regard to shorted circuits.

The circuit arrangement according to the invention is particularly suited to diagnose a heating resistor, which is deployed to heat a sensor. Provision is made, for example, for an exhaust gas sensor to serve as a sensor to acquire the concentration of exhaust gas components of an internal combustion engine. In such applications a more cost effective implementation with regard to a series production plays a decisive role.

Advantageous embodiments and configurations of the circuit arrangement according to the invention result from the dependent claims.

Provision is made in one embodiment that an initial time interval is specified during the cut-out time of the heating current, that an acquisition of the source voltage of the power source during the first time interval and a memory for the depositing of the recorded source voltage of the power source are provided, that a second time interval subsequent to the first time interval is specified, that means to supply a diagnostic current to a heating element during the second time interval are provided, that the diagnostic voltage is measured as a measurement for the voltage at the heating resistor in the second time interval and that subsequently provision is made for the voltage difference at the heating resistor to be ascertained from the source voltage of the power source deposited in the first memory and from the diagnostic voltage.

This embodiment allows first for the ascertainment of a source voltage of the power source within the first time interval. The acquisition of the voltage can be implemented with simple means as a result of the omission of the otherwise interfering heating current. In the second time interval a definite diagnostic current can be specified, whose amount can be optimally set exclusively in regard to the measuring task to be implemented and independent of the heating current. A high signal-to-noise ratio can thereby be achieved.

In order to supply the diagnostic current during the second time interval, the heating resistor connected to the power source is connected according to one embodiment to a series connection, which has a second switch and a current limiting resistor. The current limiting resistor establishes the diagnostic current.

Provision is made in one embodiment, that the length of the first specified time interval is synchronized to the recording of a mean value of the source voltage of the energy source. The energy source concerns, for example, a battery, which is disposed, for example in a motor vehicle. The voltage of such a battery can fluctuate considerably as a function of the condition of the battery and particularly as a function of the charge state. The establishment of the length of the first time interval determines the integration time to maintain the mean value.

Provision is made in a corresponding embodiment, that the length of the second specified time interval is attuned to the acquisition of a mean value of the diagnostic voltage as a measurement for the voltage at the heating resistor. While according to one embodiment the diagnostic current is directly supplied by the power source, the same importance is attributed to the averaging of the diagnostic voltage as a measurement for the voltage at the heating resistor as is to the acquisition of the source voltage of the power source itself.

On the basis of considerations, which have been confirmed by experiments, an establishment of the length of the first and/or second specified time interval at a time of two—thirty five milliseconds, preferably two—ten milliseconds, at least approximately five milliseconds, has turned out to be optimal.

Provision is made in an alternative example of embodiment of the circuit arrangement according to the invention, that at least during one part of the cut-out time of the heating current, the heating resistor is separated from the power source and is instead connected to a current source, whose current strength is adjusted to the diagnostic current. The diagnostic current is made known in the alternative example of embodiment. It is independent from the source voltage of the power source, which, therefore, does not need to be ascertained. On account of this, a shorter measuring time becomes possible.

Provision is made in an embodiment with technical circuitry, that a low-pass filter is deployed to acquire the mean value of the voltages. A first-order low-pass filter is already suitable, which can cost effectively be implemented with a resistor-condenser-combination.

Provision is made in another embodiment with technical circuitry to provide a voltage divider to acquire the voltage at the heating resistor. The voltage divider allows for the establishment of a voltage measurement range at a value, which lies in the admissible input voltage range of an analog/digital transducer.

An advantageous embodiment provides for the ascertainment of the resistance of the heating resistor at a known temperature, which preferably occurs in a stationary condition. With this measure a calibration can be implemented, which makes it possible to associate a temperature with the acquired resistance of the heating resistor during the heating operation. Proceeding from the known characteristic curve of the material of the heating resistor, which reflects the connection between the resistance and the temperature, a conversion of the resistance of the heating resistor to the actual temperature at hand can be undertaken. The adaptation of the characteristic curve can occasionally be repeated during the deployment of the circuit arrangement according to the invention with consideration given to the long-term drift of the resistance of the heating resistor. The characteristic curve can, however, also be specifically ascertained during manufacture for the heating resistor being used and ultimately be deposited.

Additional advantageous embodiments and configurations of the circuit arrangement according to the invention result from additional dependent claims and from the following description.

### DRAWINGS

FIG. 1 shows a block diagram of a circuit arrangement according to the invention.

FIG. 2 shows an alternative example of embodiment, and FIGS. 3a as well as 3b show signal progressions as a function of time, which appear in the circuit arrangement according to the invention.

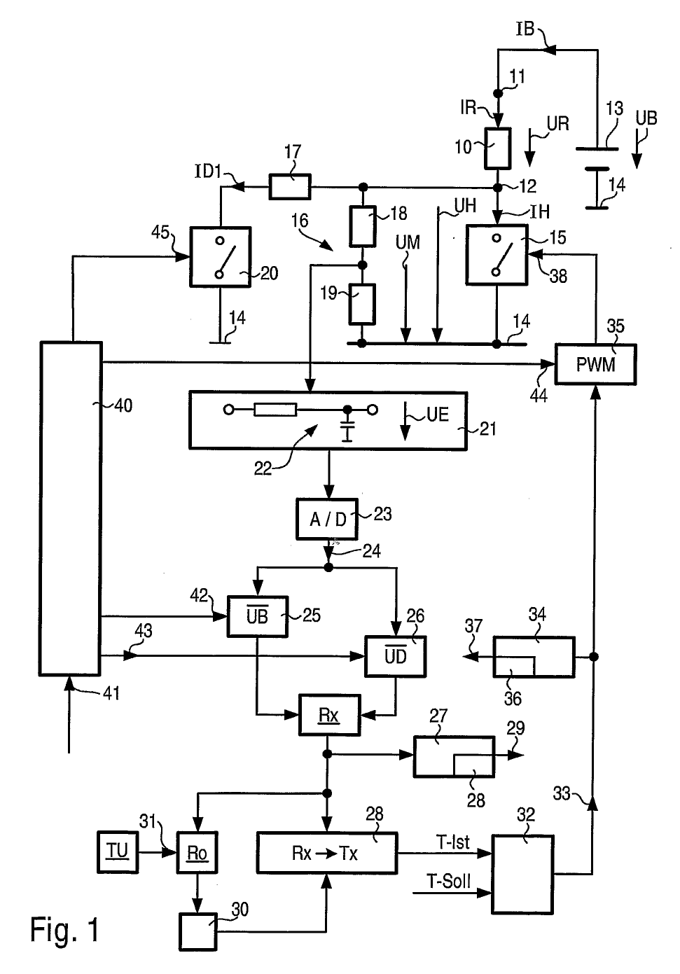

FIG. 1 shows a heating resistor 10, which has a first and second terminal 11, 12. A voltage drop UR occurs at the heating resistor 10, through which a current IR flows. The first terminal 11 is connected to a power source 13, which has a source voltage UB and supplies a source current IB. The power source 13 is attached to a circuit ground 14.

The second terminal 12 of the heating resistor 10 is combinable with the circuit ground 14 by way of a first switch 15. When the first switch 15 is closed, a heating current IH flows through the first switch 15. A voltage divider 16 as well as a current limiting resistor 17 are additionally attached to the first terminal 12. The voltage divider 16 contains a first voltage divider resistor 18, which is attached to the second terminal 12 as well as a second voltage divider resistor 19, which is attached to the circuit ground 14.

A voltage UH to the ground 14 occurring at the heating resistor 10 can be measured at the second terminal 12. This voltage appears at the voltage divider 16 as mid-voltage UM.

The voltage limiting resistor 17, through which an initial diagnostic current ID1 flows, is combinable with the circuit ground 14 by way of a second switch 20.

The mid-voltage arrives at an analog/digital transducer 23 as input voltage via a filter 21, which contains a low-pass filter implemented as a resistor-condenser-combination. A digitized input signal is deposited in a first and second memory 25, 26. Both memories 25, 26 are connected to a resistance ascertainment Rx. The resistance ascertainment Rx makes the ascertained resistance available to a diagnostic configuration 27, a third memory RO as well as a conversion 28.

The first diagnostic configuration 27 contains a first reference 28 and emits a first diagnostic signal 29.

The third memory RO is connected with the conversion 28 by way of a characteristic curve 30. A third memory RO is supplied with a first memory signal 31, which provides an ascertainment of the ambient air temperature TU.

The conversion 28 supplies an actual temperature T-Ist of the heating resistor, which is compared with a specified set point temperature T-Soll by a controller (for closed loop control). The controller 32 supplies an actuating variable, which is made available to a second diagnosis 34 and an activation drive 35. The second diagnosis 34 contains a second reference 36 and emits a second diagnostic signal 37. The activation drive 35 activates the first switch 15 with a first switching signal 38.

A timer 40 supplies the first memory 25 as a function of a diagnostic demand 41 with a second memory signal 42 and the second memory 26 with a third memory signal 43. Furthermore, the timer 40 emits a second switching signal 44 to the activation drive 35.

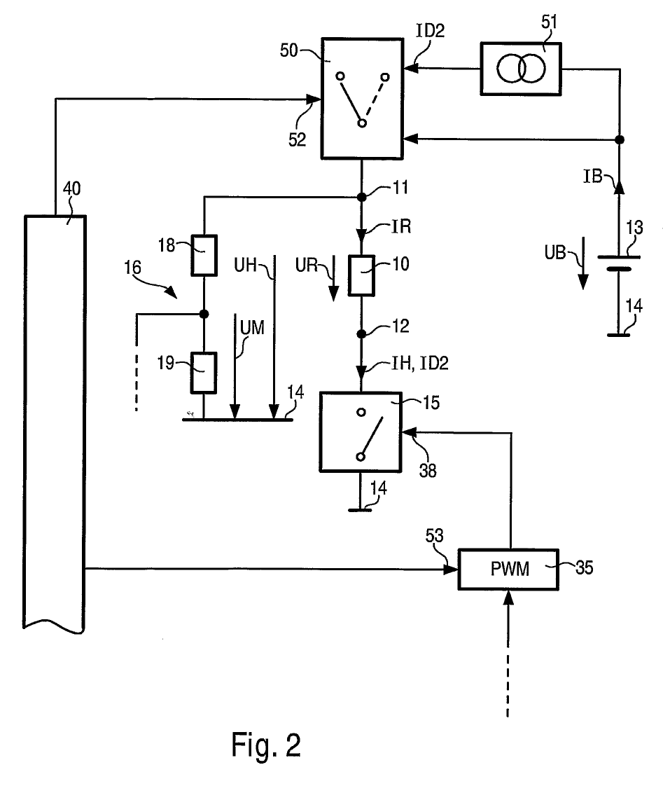

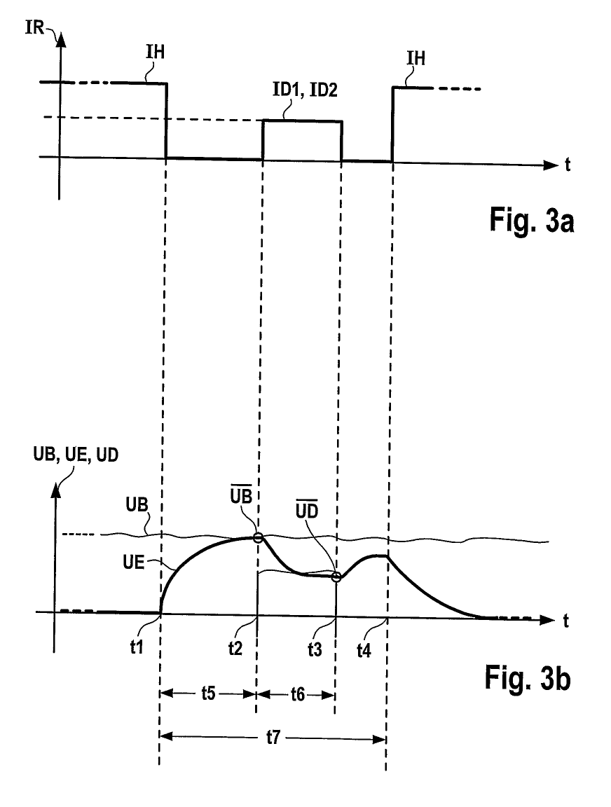

FIG. 2 shows an alternative example of embodiment of the circuit arrangement according to the invention, whereby only those components are shown, which differ from the example of embodiment shown in FIG. 1. The components which are analogous in both figures are denoted identically.

The first terminal 11 of the heating resistor 10 is connected to a change-over switch 50, which connects the first terminal 11 of the heating resistor 10 either with the power source 13 or with a current source 51. The current source 51 attached to the power source 13 supplies a second diagnostic current ID2. The second terminal 12 of the heating resistor 10 is in this example of embodiment connected only to the first switch 15. The second diagnostic current ID2 can, therefore, flow in addition to the heating current IH through the first switch 15.

The timer 40 activates the change-over switch 50 with a third switching signal 52 and the activation drive 35 with a fourth switching signal 53.

FIG. 3a shows the current IR flowing in the heating resistor 10 as a function of the time t. The heating current IH flows up to a first time point t1. Up to a second time point t2, there is at least approximately no current flowing. Between the second time point t2 and a third time point t3 either the first or the second diagnostic current ID1, ID2, is flowing. After the third time point t3 up to a fourth time point t4 there is again at least approximately no current flowing. From the fourth time point 14 on the heating current IH is flowing again.

A first specified time interval t5 lies between the first and second time point t1, t2, and a second specified time interval t6 lies between the second and third time point t2 and t3. A cut-out time t7 lies between the first and fourth time point t1, t4.

FIG. 3b shows the source voltage UB of the power source 13, the input voltage UE of the analog/digital transducer 23 and a diagnostic voltage UD, which in each case are shown as a function of the time t. The input voltage UD is at least approximately zero up to the first time point t1. The input voltage UE increases in the first time interval t5 at least approximately to the amount of the source voltage UB. In the second time interval t6 the input voltage UE drops to the diagnostic voltage UD. After the third time point t3 the input voltage UE increases. From the fourth time point t4 on the input voltage UE drops again back to at least approximately zero.

The circuit arrangement according to the invention works in the following manner:

Provision is made according to the first example of embodiment, that the first terminal 11 of the heating resistor 10 is constantly connected to the power source 13. The heating resistor 10 serves, for example, to heat a sensor. Preferably provision is made for the sensor to be an exhaust gas sensor, which detects an exhaust gas component of an unspecified internal combustion engine. The heating resistor 10 is stressed with an electrical output, which is supplied by the power source 13. The first switch 15, which switches the heating current IH, is designed to operate the heating resistor 10.

A first possibility provides for the first switch 15 to be constantly switched on during the heating operation. Provision is made in a preferred embodiment for the first switch 15 to be clock activated. The first switching signal 38, which supplies the activation drive 35, is delivered to the first switch 15 for this purpose. The activation drive 35 establishes, for example, the cycle duration and/or the duty cycle of the first switching signal 38 as a function of the actuating variable 33. Within the framework of the clock activated operation of the heating resistor 10, a median voltage UR arises at the heating resistor 10 due to the periodic on and off switching of the heating current IH.

A diagnosis is supposed to be implemented during the cut-out time t7 according to the first example of embodiment. If need be the diagnosis is initiated with the diagnostic demand 41. The diagnosis can be implemented within a cut-out time, which occurs in any event within the framework of the clock activated operation. In case the cut-out time t7 should be too short or is not present, the timer 40 assures with the second switching signal 44 delivered to the activation drive 35 that the cut-out time occurs. Alternatively the second switching signal 44 can be delivered directly to the first switch 15.

The diagnosis begins in the first specified time interval t5 with the acquisition of the source voltage UB of the power source 13. The power source 13 is, for example, a battery disposed in a motor vehicle, whose source voltage UB fluctuates as a function of the battery condition and especially as a function of the charge state around a rated value. In the case of a 12 volt battery the rated voltage lies, for example, at 14 volts during operation of the motor vehicle. The source voltage UB can fluctuate, for example, between 12.5 volts and 15 volts. It is, therefore, generally not sufficient to record the momentary source voltage UB. The length of the first time interval t5 is to be measured in such a way, that an averaging can be implemented. A length of the first interval t5 which is too short is not sufficient to record a mean value. A time expansion is limited in consideration of the time allocated for the diagnosis. In practice a length of the first time interval in the range of 2-35, preferably 2-10 milliseconds has proven to be a good compromise. The length of the first time interval t5 is established specifically at least approximately at 5 milliseconds.

Before the first time point t1, the voltage UH at the heating resistor 10 is at least approximately zero due to the first switch 15 being switched on. The voltage UH at the heating resistor 10 corresponds to the drop in voltage at the first switch 15 due to its residual resistance, when connected straight through, multiplied by the heating current IH. The first switch 15 is opened at the first time point t1. Instead of the heating current IH, a current IR flows through the heating resistor 10 from the first time point t1 forward. This current is determined by the entire resistance of the heating resistor 10 plus both of the resistances of the voltage dividers 18, 19. Both of the resistances of the voltage dividers 18, 19 are designed more highly resistive in comparison to the resistance of the heating resistor, so that only a slight amount of current IR flows through the heating resistor 10 and the voltage divider 16. The voltage divider ratio is adjusted in such a manner, that the mid-voltage UM is adjusted to the working range of the subsequent analog/digital transducer 23.

Provision is made for the filter 21 to form a mean value of the source voltage UB. The aforementioned filter is disposed in front of the analog/digital transducer 23 in the example of embodiment depicted. The filter 21 has integral properties. For example, a first order or higher low-pass filter is suitable. A first order low-pass filter, which is implemented with a resistor-condenser-combination, has proven to be economically feasible and well suited for the implementation of the task. Besides averaging, the filter 21 additionally has the task of keeping away interfering signals from the analog/digital transducer 23. During the first time interval t5, the input voltage UE increases at the input of the analog/digital transducer 23 at least approximately to the median value of the source voltage UB.

When changing from the first to the second time interval t5, t6, the input signal UE, which the analog/digital transducer 23 already during the first time interval t5 makes constantly available as a digital input signal 24, is deposited in the first memory. The deposition is induced by the second memory signal 42, which the timer 40 provides.

The heating resistor 10 is stressed with the first diagnostic current ID1 at the second time point t2. During the second specified time interval t6, the timer 40 closes the second switch 20 with a third switching signal 45, so that the voltage divider 16 is bridged by a connection in series, which contains the current limiting resistor 17 and the second switch 20. The current limiting resistor 17 is, for example, fixed at a value, which corresponds to a specified proportion of the heating current IH. It is assumed in the depicted example of embodiment that the first diagnostic current ID1 is set to, for example, 50% of the heating current. In contrast the current flowing through the voltage divider 16 can completely be ignored.

The diagnostic voltage UD is measured in the second time interval t6, which is a measurement for the voltage UH at the heating resistor 10. The diagnostic voltage is deposited in the second memory 26. The voltage UR at the heating resistor 10 corresponds to the difference in voltage between the source voltage UB of the power source 13 and the voltage UH at the second terminal 12 of the heating resistor 10. As the first diagnostic current ID1 is obtained from the power source 13, fluctuations must likewise be anticipated when ascertaining the diagnostic voltage UD. Therefore, preferably provision is also made in the second time interval t6 for an averaging during the recording of the diagnostic voltage UD.

The mean value of the diagnostic voltage UD is available at the third time point t3 at the end of the second time interval t6. The second time interval t6 is likewise established preferably at a theoretically and experimentally ascertained length of 2-35 milliseconds, preferably 2-10 milliseconds, specifically 5 milliseconds. A simple implementation of the timer 40 provides for the establishment of the first and second time interval t5, t6 at the same length and, therefore, here specifically at least approximately 5 milliseconds.

At the third time point t3 the diagnostic current UD is deposited in the second memory 26, when the third memory signal 42 is provided.

After the third time point t3 the heating resistor can again be stressed with the heating current IH. In the example of embodiment depicted the cut-out time t7 is not yet elapsed at the third time point t3. Therefore, the input voltage UE increases once again up to the fourth time point, until it drops again at least approximately to the value of zero with the appearance of the heating current IH, as the first switch 15 is switched on at the fourth time point t4 and at least approximately short-circuits the voltage divider 16.

The resistance ascertainment Rx can ascertain the resistance of the heating resistor 10 using the difference of the median voltages UB, UD deposited in the first and second memory 25, 26 and using the first diagnostic current ID1. The first diagnostic current ID1 is obtained from the diagnostic voltage UD and the known value of the current limiting resistor 17.

After the resistance of the heating resistor 10 has been ascertained, the first diagnostic configuration 27 can already implement a diagnosis. The first diagnostic configuration 27 checks the resistance ascertained by way of a comparison with the first reference 28 in regard to the exceeding of and/or shortfall to the specified threshold values. The first diagnostic configuration 27 supplies the first diagnostic signal 29 as a function of the result. This signal can be displayed and/or deposited in an unspecified mistake memory.

Provision is made in an advantageous configuration of the circuit arrangement according to the invention, that the resistance of the heating resistor 10 is converted to the actual temperature of the heating resistor 10. In so doing, provision is made for the conversion 28, which calculates the temperature from the resistance ascertained and the characteristic curve 30. The characteristic curve 30 constructs the relationship between the temperature and the resistance of the heating resistor 10. Well documented is the relationship using a platinum element as a heating resistor 10. The resistance of the heating element at a specified temperature is necessary to know. A calibration can be performed at a specified ambient air temperature, for example 20° C., whose presence establishes the ascertainment of the ambient air temperature TU. The ambient air temperature ascertainment TU preferably determines, if the specified temperature is present for a specified time period. If this applies, it can be assumed, that the resistance of the heating resistor has likewise assumed the ambient air temperature. The value of the resistance which hereby appears is deposited in the third memory RO and is taken into regard when ascertaining the characteristic curve 30. In the result the conversion 28 provides the actual temperature T-ist of the resistance of the heating resistor 10. Provision is made for this embodiment if a long-term drift of the heating resistor 10 can not be ruled out. The characteristic curve 30 is occasionally adjusted as a function of need during the deployment of the circuit arrangement according to the invention with the heating resistor 10. Provided that a long-term drift of the heating resistor 10 can be disregarded, it is sufficient to ascertain the characteristic curve 30 within the framework of the manufacture and to lastingly deposit it.

An advantageous embodiment provides for the actual temperature T-ist of the heating resistor 10 to be fixed at a specified set point temperature T-Soll. The closed-loop control 32 compares the actual temperature T-ist with the specified set point temperature T-Soll and establishes the actuating variable 33, which is delivered to the activation drive 35, as a function of the difference. The activation drive 35 establishes the first switching signal 38 in such a manner, preferably in a pulse-width-modulated operation, that the set point temperature is achieved.

The alternative example of embodiment of the circuit arrangement according to the invention depicted in FIG. 2 provides for the diagnostic current of the current source 51 to be specified as a second diagnostic current ID2. In this example of embodiment it is not required to ascertain the median source voltage UB of the power source 13.

During the heating operation, the change-over switch 50 is stressed by the third switching signal 52 in such a manner, that the heating resistor 10 is directly connected to the power source 13. In the implementation of the diagnosis, the third switching signal 52 initiates a direct switching over to the current source 51 within the cut-out time t7, which occurs, however, at the earliest, at the first time point t1. Furthermore, in the implementation of the diagnosis the first switch 15 is closed by way of the fourth switching signal 53.

The length of the time interval to be specified for the implementation of the measuring in this example of embodiment must only be established with regard to the requirements for the signal acquisition and the signal evaluation, because an averaging is not applicable here. It can, therefore, in comparison with the length of the second time interval t6 be considerably shorter. The interval in a borderline case coincides with the cut-out time t7.

During the time interval the diagnostic voltage UD is acquired as a measurement for the voltage UH occurring at the heating element 10. This voltage UH corresponds directly to the voltage UR at the heating resistor 10, as the second terminal 12 of the heating resistor 10 is connected to the circuit ground 14 via the first switch 15. The resistance ascertainment Rx can thus ascertain the current (momentary) resistance of the heating resistor 10 directly from the acquired signal and the known second diagnostic current ID2.

The diagnosis can again be implemented with the first diagnostic configuration 27, the second diagnostic configuration 34 and/or with additional unspecified diagnostic configurations.

1. A circuit arrangement to diagnose a heating resistor, which is connected in series with a first switch that connects the heating resistor to a power source for the operation of the heating resistor with a heating current, the circuit arrangement including first circuitry that operates the heating resistor with a diagnostic current during a cut-out time of the heating current, acquires a diagnostic voltages as a measurement for the voltage occurring at the heating resistor during the cut-out time and calculates a resistance of the heating resistor to be used as a basis for the diagnosis.

2. A circuit arrangement according to claim 1, wherein a first time interval is specified during the cut-out time of the heating current and acquiring a source voltage of the power source during a first time interval and a first memory for the deposition of the acquired source voltage of the power source specifying a second time interval subsequent to a first time interval, in that provision is made that stresses the heating resistor with the diagnostic current during the second time interval, in that the diagnostic current is measured at the heating resistor in the second time interval and in that subsequently provision is made to ascertain a voltage differences at the heating resistor from the source voltages of the power source deposited in the first memory and the diagnostic voltage as a measurement for the voltage at the heating resistor.

3. A circuit arrangement according to claim 2, wherein during the second time intervals, the heating resistor is connected by way of a series circuit with a second switch and a current limiting resistor to the power source for the purpose of supplying the diagnostic current.

4. A circuit arrangement according to claim 2, wherein a length of the first specified time interval is attuned to an acquisition of a mean value of the source voltage of the power source.

5. A circuit arrangement according to claim 2, wherein the length of the second specified time interval is attuned to an acquisition of a mean value of the diagnostic voltage as a measurement for the voltage at the heating resistor.

6. A circuit arrangement according to claim 4, wherein a length of the first or second specified time interval is established at a time of 2-35 milliseconds.

7. A circuit arrangement according to claim 1, wherein a time interval is specified at least during a part of the cut-out time of the heating current, in that during the time interval, the heating resistor is disconnected from the power source and connected to a current source, whose current strength is adjusted to the diagnostic current and in that the diagnostic voltages is measured as a measurement for the voltage at the heating resistor in the specified time interval.

8. A circuit arrangement according to claim 1, wherein provision is made for a low-pass filter to ascertain a mean value of the acquired voltages.

9. A circuit arrangement according to claim 1, wherein provision is made for a voltage dividers to acquire the voltages.

10. A circuit arrangement according to claim 1 wherein the resistance of the heating resistor ascertained at a specified temperature is taken into consideration in an establishment of a characteristic curve, and in that using the characteristic curve a conversion converts the ascertained resistance of the heating resistor into an actual temperature.
